(19) United States
(12) Patent Application Publication
(10) Pub. No.: US 2019/0122863 A1
(43) Pub. Date: Apr. 25, 2019

(54) PLASMA PROCESSING APPARATUS

(71) Applicant: Tokyo Electron Limited, Tokyo (JP)

(72) Inventors: Kazuya Nagaseki, Kurokawa-gun, Miyagi (JP); Tatsuro Ohshita, Kurokawa-gun, Miyagi (JP); Koichi Nagami, Kurokawa-gun, Miyagi (JP)

(21) Appl. No.: 16/096,759

(22) PCT Filed: Apr. 14, 2017
(86) PCT No.: PCT/JP2017/015298

§ 371 Date: Oct. 26, 2018

(30) Foreign Application Priority Data
Apr. 28, 2016 (JP) 2016-090810
Jul. 4, 2016 (JP) 2016-132685

(51) Int. Cl. H01J 37/32

(52) U.S. Cl. CPC H01J 37/32174; H01J 37/32715; H01L 21/67069; H01J 37/32091; H01J 37/32568

(57) ABSTRACT

Energy of ions irradiated to a chamber main body is reduced. A plasma processing apparatus includes a chamber main body, a placing table and a high frequency power supply unit. The chamber main body is configured to provide a chamber therein. The chamber main body is connected to a ground potential. The placing table has a lower electrode and is provided within the chamber. The high frequency power supply unit is electrically connected to the lower electrode. The high frequency power supply unit is configured to generate an output wave for bias to be supplied to the lower electrode. The high frequency power supply unit is configured to generate the output wave in which a positive voltage component of a voltage waveform of a high frequency power having a fundamental frequency is reduced.

### TECHNICAL FIELD

The various embodiments described herein pertain generally to a plasma processing apparatus.

### BACKGROUND ART

In the manufacture of an electronic device such as a semiconductor device, a plasma processing apparatus is used. In general, the plasma processing apparatus is equipped with a chamber main body, a placing table and a high frequency power supply. An internal space of the chamber main body is configured as a chamber. The chamber main body is grounded. The placing table is provided within the chamber and configured to hold a processing target object placed thereon. The placing table includes a lower electrode. The high frequency power supply is connected to the lower electrode. In this plasma processing apparatus, plasma of a processing gas is generated within the chamber, and a high frequency power for bias (“high frequency bias power”) from the high frequency power supply is supplied to the lower electrode. In this plasma processing apparatus, ions are accelerated by a potential difference between an electric potential of the lower electrode based on the high frequency bias power and an electric potential of the plasma, and the accelerated ions are irradiated to the processing target object.

In the plasma processing apparatus, a potential difference is also generated between the chamber main body and the plasma. If the potential difference between the chamber main body and the plasma is large, energy of the ions irradiated to the chamber main boy is increased, so that particles are released from the chamber main body. These particles released from the chamber main body contaminate the processing target object placed on the placing table. To suppress the generation of these particles, Patent Document 1 discloses a technique using an adjustment device configured to adjust a grounding capacity of the chamber. The adjustment device described in Patent Document 1 is configured to adjust an area ratio between an anode and a cathode facing the chamber, that is, an A/C ratio. The larger the A/C ratio is, that is, the larger a ratio of an area of the anode to an area of the cathode is, the smaller the potential difference between the chamber main body and the plasma becomes. Accordingly, the energy of the ions irradiated to the chamber main body is lowered. If the energy of the ions irradiated to the chamber main body is lowered, the generation of the particles is suppressed.

Patent Document 1: Japanese Patent Laid-open Publication No. 2011-228694

### DISCLOSURE OF THE INVENTION

### Problems to be Solved by the Invention

In an etching processing as one kind of plasma processing upon the processing target object, it is required to form a shape having a higher aspect ratio on the processing target object. To form such a shape with a higher aspect ratio on the processing target object, the energy of the ions irradiated to the processing target object needs to be increased. Setting a frequency of the high frequency bias power to be low is one of the ways to increase the energy of the ions irradiated to the processing target object. If the frequency of the high frequency bias power is reduced, however, the electric potential of the plasma is increased. If the electric potential of the plasma is increased, the potential difference between the plasma and the chamber main body is increased, which results in an increase of the energy of the ions irradiated to the chamber main body. From this background, it is required to reduce the energy of the ions irradiated to the chamber main body.

### Means for Solving the Problems

In an exemplary embodiment, there is provided a plasma processing apparatus. The plasma processing apparatus includes a chamber main body, a placing table and a high frequency power supply unit. The chamber main body is configured to provide a chamber therein. The chamber main body is connected to a ground potential. The placing table has a lower electrode and is provided within the chamber. The high frequency power supply unit is electrically connected to the lower electrode. The high frequency power supply unit is configured to generate an output wave for bias to be supplied to the lower electrode. The high frequency power supply unit is configured to generate the output wave in which a positive voltage component of a high frequency power having a fundamental frequency is reduced.

In the plasma processing apparatus according to the exemplary embodiment, since the output wave having the reduced positive voltage component is supplied to the lower electrode, a potential of plasma is lowered. Accordingly, a potential difference between plasma and the chamber main body is decreased. As a result, energy of ions irradiated to the chamber main body is reduced. Accordingly, particle generation from the chamber main body is suppressed. Further, by setting a frequency (fundamental frequency) of the output wave to be low, it is possible to increase energy of ions irradiated to a processing target object while reducing the energy of the ions irradiated to the chamber main body.

The high frequency power supply unit may include multiple high frequency power supplies and a combiner. The multiple high frequency power supplies are respectively configured to generate multiple high frequency powers having different frequencies n times or 2n times larger than the fundamental frequency. Here, n denotes an integer equal to or higher than 1. The combiner is configured to generate the output wave by combining the multiple high frequency powers. According to this exemplary embodiment, it is possible to generate the output wave while suppressing a loss of the high frequency powers from the high frequency power supplies.

In the exemplary embodiment, the high frequency power supply unit may include a high frequency power supply configured to generate the high frequency power having the fundamental frequency; and a half-wave rectifier configured to remove the positive voltage component of the high frequency power generated from the high frequency power supply. According to this exemplary embodiment, the positive voltage component is removed substantially completely.

In the exemplary embodiment, the plasma processing apparatus is configured as a capacitively coupled plasma processing apparatus. The plasma processing apparatus further includes an upper electrode and a first high frequency power supply. The upper electrode is provided above the lower electrode. The first high frequency power supply is connected to the upper electrode and configured to generate a high frequency power for plasma generation. In the plasma processing apparatus in which the upper electrode is configured as an electrode to which the high frequency power for plasma generation is supplied, an area of an anode electrode is small and an A/C ratio is small. Accordingly, in the plasma processing apparatus according to the present exemplary embodiment, the aforementioned output wave may be used more advantageously.

In the exemplary embodiment, the fundamental frequency is equal to or less than 1.4 MHz.

In the exemplary embodiment, the plasma processing apparatus may further include a second high frequency power supply connected to the lower electrode. The second high frequency power supply is configured to generate a high frequency power for bias having a frequency higher than the fundamental frequency. In the plasma processing apparatus according to the present exemplary embodiment, either the aforementioned output wave or the high frequency power for bias generated from the second high frequency power supply is selectively supplied to the lower electrode depending on a process involved.

### Effect of the Invention

According to the exemplary embodiment as stated above, it is possible to reduce the energy of the ions irradiated to the chamber main body.

### BRIEF DESCRIPTION OF THE DRAWINGS

FIG. 1 is a diagram schematically illustrating a plasma processing apparatus according to an exemplary embodiment.

FIG. 2 is a diagram illustrating a high frequency power supply unit according to the exemplary embodiment.

FIG. 3 is a diagram illustrating an example of an output wave which can be generated by the high frequency power supply unit shown in FIG. 2.

FIG. 4 is a diagram illustrating a high frequency power supply unit according to another exemplary embodiment.

FIG. 5 is a diagram illustrating an example of an output wave generated by the high frequency power supply unit shown in FIG. 4.

FIG. 6A is a diagram showing an energy distribution of ions irradiated to a processing target object calculated in Simulation No. 1, and FIG. 6B is a diagram showing an energy distribution of ions irradiated to a chamber main body 12 calculated in Simulation No. 1.

FIG. 7A is a diagram showing an energy distribution of the ions irradiated to the processing target object calculated in Simulation No. 2, and FIG. 7B is a diagram showing an energy distribution of the ions irradiated to the chamber main body 12 calculated in Simulation No. 2

FIG. 8A is a diagram showing an energy distribution of the ions irradiated to the processing target object calculated in Simulation No. 3, and FIG. 8B is a diagram showing an energy distribution of the ions irradiated to the chamber main body 12 calculated in Simulation No. 3.

FIG. 9A is a diagram showing an energy distribution of the ions irradiated to the processing target object calculated in Simulation No. 4, and FIG. 9B is a diagram showing an energy distribution of the ions irradiated to the chamber main body 12 calculated in Simulation No. 4.

FIG. 10 is a diagram showing incident angles of the ions calculated in Simulation No. 5 and Simulation No. 6.

FIG. 11A is a diagram showing an energy distribution of the ions irradiated to the processing target object calculated in Simulation No. 7, and FIG. 11B is a diagram showing an energy distribution of the ions irradiated to the chamber main body 12 calculated in Simulation No. 7.

FIG. 12A is a diagram showing an energy distribution of the ions irradiated to the processing target object calculated in Simulation No. 8, and FIG. 12B is a diagram showing an energy distribution of the ions irradiated to the chamber main body 12 calculated in Simulation No. 8.

FIG. 13 is a table showing results of Simulation Nos. 9 to 14. FIG. 14 is a graph showing Eh/Ef calculated based on results of Simulation Nos. 15 to 30.

FIG. 15A is a diagram showing an energy distribution of the ions irradiated to the processing target object calculated in Simulation No. 31, and FIG. 15B is a diagram showing an energy distribution of the ions irradiated to the chamber main body 12 calculated in Simulation No. 31.

FIG. 16A is a diagram showing an energy distribution of the ions irradiated to the processing target object calculated in Simulation No. 32, and FIG. 16B is a diagram showing an energy distribution of the ions irradiated to the chamber main body 12 calculated in Simulation No. 32.

FIG. 17 is a diagram illustrating a high frequency power supply unit according to yet another exemplary embodiment.

FIG. 18 is a diagram illustrating an example of a second output wave which can be generated by the high frequency power supply unit shown in FIG. 17.

FIG. 19 is a diagram illustrating a high frequency power supply unit according to still yet another exemplary embodiment.

FIG. 20 is a diagram illustrating an example of a second output wave generated by the high frequency power supply unit shown in FIG. 19.

FIG. 21A is a diagram showing an energy distribution of the ions irradiated to the processing target object calculated in Simulation No. 33, and FIG. 21B is a diagram showing an energy distribution of the ions irradiated to the chamber main body 12 calculated in Simulation No. 33.

FIG. 22A is a diagram showing an energy distribution of the ions irradiated to the processing target object calculated in Simulation No. 34, and FIG. 22B is a diagram showing an energy distribution of the ions irradiated to the chamber main body 12 calculated in Simulation No. 34.

### DETAILED DESCRIPTION

Hereinafter, various exemplary embodiments will be described in detail with reference to the accompanying drawings which form a part of the description. In the various drawings, same or corresponding parts will be assigned same reference numerals.

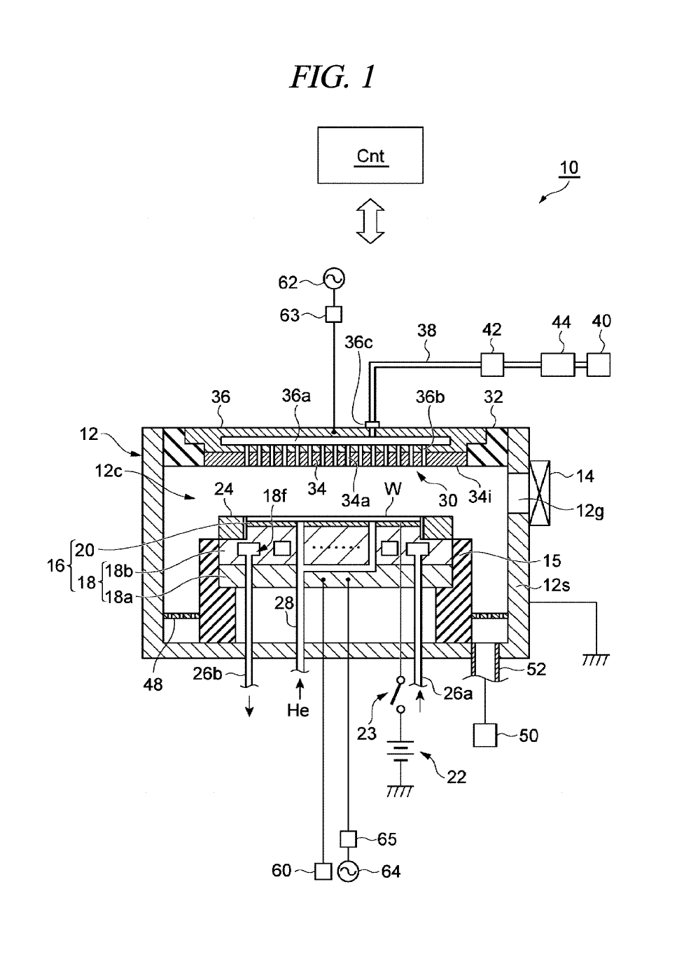

FIG. 1 is a diagram schematically illustrating a plasma processing apparatus according to an exemplary embodiment. In FIG. 1, a structure of a longitudinal cross section of the plasma processing apparatus according to the exemplary embodiment is schematically illustrated. A plasma processing apparatus 10 shown in FIG. 1 is configured as a capacitively coupled plasma processing apparatus. The plasma processing apparatus 10 may be used for performing, by way of example, plasma etching.

The plasma processing apparatus 10 is equipped with a chamber main body 12. The chamber main body 12 has a substantially cylindrical shape. An internal space of the chamber main body 12 is configured as a chamber 12c. The chamber main body 12 is made of, by way of example, but not limited to, aluminum. A plasma-resistant film is formed on an inner wall surface of the chamber main body 12, that is, on a wall surface confining the chamber 12c. This film may be a film formed by anodic oxidation or a film made of ceramic such as yttrium oxide. Further, an opening 12g through which a processing target object W is transferred is provided at a sidewall 12s of the chamber main body 12. This opening 12g is configured to be opened or closed by a gate valve 14. The chamber main body 12 is connected to the ground potential.

Within the chamber 12c, a supporting member 15 is upwardly extended from a bottom of the chamber main body 12. The supporting member 15 has a substantially cylindrical shape and is made of an insulating material such as quartz. Further, a placing table 16 is provided within the chamber 12c. The placing table 16 is configured to hold the processing target object W on a top surface thereof. The processing target object W may have a disk shape such as a wafer. The placing table 16 includes a lower electrode 18 and an electrostatic chuck 20. This placing table 16 is supported by the supporting member 15.

The lower electrode 18 includes a first plate 18a and a second plate 18b. The first plate 18a and the second plate 18b are made of a metal such as, but not limited to, aluminum and have a substantially disk shape. The second plate 18b is provided on the first plate 18a and electrically connected with the first plate 18a.

The electrostatic chuck 20 is provided on the second plate 18b. The electrostatic chuck 20 includes an insulating layer and an electrode embedded within the insulating layer. The electrode of the electrostatic chuck 20 is electrically connected to a DC power supply 22 via a switch 23. If a DC voltage from the DC power supply 22 is applied to the electrode of the electrostatic chuck 20, the electrostatic chuck 20 generates an electrostatic force such as a Coulomb force. The electrostatic chuck 20 attracts and holds the processing target object W by this electrostatic force.

A focus ring 24 is provided on a peripheral portion of the second plate 18b to surround an edge of the processing target object W and the electrostatic chuck 20. The focus ring 24 is configured to improve uniformity of plasma processing. The focus ring 24 is made of a material which is appropriately selected depending on the plasma processing involved. For example, the focus ring 24 may be made of quartz.

A path 18f is provided within the second plate 18b. A coolant is supplied into the path 18f from a chiller unit provided outside the chamber main body 12 via a pipeline 26a. The coolant supplied into the path 18f is then returned back into the chiller unit via a pipeline 26b. In this way, the coolant is supplied into the path 18f to be circulated therein. By controlling a temperature of this coolant, a temperature of the processing target object W held by the electrostatic chuck 20 is controlled.

Furthermore, the plasma processing apparatus 10 is provided with a gas supply line 28. Through the gas supply line 28, a heat transfer gas, e.g., a He gas, from a heat transfer gas supply device is supplied into a gap between a top surface of the electrostatic chuck 20 and a rear surface of the processing target object W.

The plasma processing apparatus 10 is further equipped with an upper electrode 30. The upper electrode 30 is provided above the placing table 16 substantially in parallel with the lower electrode 18. The upper electrode 30 closes a top opening of the chamber main body 12 along with a member 32. The member 32 has an insulation property. The upper electrode 30 is supported at an upper portion of the chamber main body 12 with this member 32 therebetween.

The upper electrode 30 is equipped with a ceiling plate 34 and a supporting body 36. The ceiling plate 34 faces the chamber 12c, and is provided with a multiple number of gas discharge holes 34a. This ceiling plate 34 is made of, by way of example, but not limitation, silicon. Alternatively, the ceiling plate 34 may have a structure in which a plasma-resistant film is provided on a surface of an aluminum base member. Further, this film may be a film formed by anodic oxidation or a film made of ceramic such as yttrium oxide.

The supporting body 36 is configured to support the ceiling plate 34 in a detachable manner, and is made of a conductive material such as, but not limited to, aluminum. A gas diffusion space 36a is formed within the supporting body 36. Multiple gas holes 36b are extended downwards from the gas diffusion space 36a, and these gas holes 36b communicate with the gas discharge holes 34a, respectively. Further, the supporting body 36 is also provided with a gas inlet opening 36c through which a processing gas is introduced into the gas diffusion space 36a, and this gas inlet opening 36c is connected to a gas supply line 38.

The gas supply line 38 is connected to a gas source group 40 via a valve group 42 and a flow rate controller group 44. The gas source group 40 includes a multiple number of gas sources. The valve group 42 includes a multiple number of valves, and the flow rate controller group 44 includes a multiple number of flow rate controllers such as mass flow controllers. Each of the gas sources belonging to the gas source group 40 is connected to the gas supply line 38 via a corresponding valve belonging to the valve group 42 and a corresponding flow rate controller belonging to the flow rate controller group 44. This plasma processing apparatus 10 is capable of supplying gas(es) from one or more gas sources selected from the multiple number of gas sources belonging to the gas source group 40 into the chamber main body 12 at individually controlled flow rate(s).

Within the chamber 12c, a baffle plate 48 is provided between the supporting member 15 and the sidewall 12s of the chamber main body 12. By way of non-limiting example, the baffle plate 48 may be made of an aluminum base member coated with ceramic such as yttrium oxide. This baffle plate 48 is provided with a multiple number of through holes. Under the baffle plate 48, a gas exhaust pipe 52 is connected to the bottom of the chamber main body 12. The gas exhaust pipe 52 is connected to a gas exhaust device 50. The gas exhaust device 50 has a vacuum pump such as a turbo molecular pump, and is configured to decompress the chamber 12c.

The plasma processing apparatus 10 is further equipped with a high frequency power supply unit 60. The high frequency power supply unit 60 is electrically connected to the lower electrode 18. This high frequency power supply unit 60 is configured to generate an output wave for bias to be supplied to the lower electrode 18. The output wave generated by the high frequency power supply unit 60 is an output wave in which a positive voltage component of a high frequency power having a fundamental frequency is reduced. In the present exemplary embodiment, the fundamental frequency may be equal to or less than 1.4 MHz. Details of this high frequency power supply unit 60 will be discussed later.

According to the exemplary embodiment, the plasma processing apparatus 10 further includes a first high frequency power supply 62. The first high frequency power supply 62 is configured to generate a first high frequency power for plasma generation having a frequency ranging from 27 MHz to 100 MHz. The first high frequency power supply 62 is connected to the upper electrode 30 via a matching device 63. The matching device 63 is equipped with a circuit configured to match an output impedance of the first high frequency power supply 62 and an input impedance at a load side (upper electrode 30 in the present exemplary embodiment). Further, the first high frequency power supply 62 may be connected to the lower electrode 18 via the matching device 63. In case that the first high frequency power supply 62 is connected to the lower electrode 18, the upper electrode 30 is connected to the ground potential.

According to the exemplary embodiment, the plasma processing apparatus 10 is further equipped with a second high frequency power supply 64. The second high frequency power supply 64 is configured to generate a second high frequency power for bias to attract ions into the processing target object W. A frequency of the second high frequency power is lower than the frequency of the first high frequency power and is higher than the fundamental frequency of the output wave generated by the high frequency power supply unit 60. The frequency of the second high frequency power may be in the range from 3.2 kHz to 13.56 MHz. The second high frequency power supply 64 is connected to the lower electrode 18 via a matching device 65. The matching device 65 is equipped with a circuit configured to match an output impedance of the second high frequency power supply 64 and an input impedance at a load side (lower electrode 18 side). By providing this second high frequency power supply 64 in addition to the high frequency power supply unit 60, it is possible to supply either the output wave from the high frequency power supply unit 60 or the high frequency power for bias from the second high frequency power supply 64 to the lower electrode 18 selectively.

In the exemplary embodiment, the plasma processing apparatus 10 may further include a control unit Cnt. The control unit Cnt is implemented by a computer including a processor, a storage device, an input device, a display device, and so forth, and controls individual components of the plasma processing apparatus 10. To elaborate, the control unit Cnt executes a control program stored in the storage device and controls the individual components of the plasma processing apparatus 10 based on recipe data stored in the storage device. Under this control, the plasma processing apparatus 10 performs a process designated by the recipe data.

When performing a plasma processing in this plasma processing apparatus 10, a gas from a gas source selected from the multiple number of gas sources belonging to the gas source group 40 is supplied into the chamber 12c. Further, the chamber 12c is decompressed by the gas exhaust device 50. Then, the gas supplied into the chamber 12c is excited by a high frequency electric field generated by the high frequency power from the first high frequency power supply 62. Accordingly, plasma is generated within the chamber 12c. Further, the output wave for bias or the second high frequency power for bias is selectively supplied to the lower electrode 18. Accordingly, ions in the plasma are accelerated toward the processing target object W. The processing target object W is processed with these accelerated ions and/or radicals.

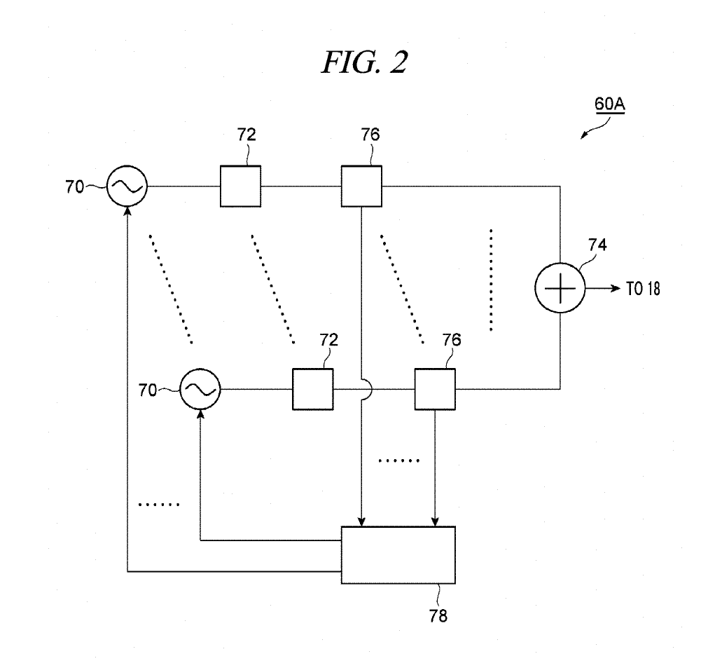

Now, details of the high frequency power supply unit 60 will be explained. FIG. 2 is a diagram illustrating a high frequency power supply unit according to an exemplary embodiment. A high frequency power supply unit 60A shown in FIG. 2 may be adopted as the high frequency power supply unit 60 of the plasma processing apparatus 10. The high frequency power supply unit 60A is equipped with a plurality of high frequency power supplies 70, a plurality of matching devices 72 and a combiner 74. The high frequency power supplies 70 are respectively configured to generate high frequency powers having different frequencies which are n times or 2n times as high as a fundamental frequency. Here, n denotes an integer equal to or larger than 1. According to the exemplary embodiment, the plurality of high frequency power supplies 70 at least include a high frequency power supply configured to generate a high frequency power of the fundamental frequency and a high frequency power supply configured to generate a high frequency power of a frequency twice as high as the fundamental frequency. The number of the high frequency power supplies 70 may be two or more.

The plurality of high frequency power supplies 70 are connected to the combiner 74 via the plurality of matching devices 72, respectively. Each of the plurality of matching devices 72 is equipped with a circuit configured to match an output impedance of a corresponding high frequency power supply among the plurality of high frequency power supplies 70 and an impedance at a load side. The combiner 74 is configured to combine (that is, add) the plurality of high frequency powers which are respectively transmitted from the plurality of high frequency power supplies 70 via the plurality of matching devices 72. The combiner 74 then supplies an output wave (composite wave) generated by combining the plurality of high frequency powers to the lower electrode 18.

In the present exemplary embodiment, the high frequency power supply unit 60A may further include a plurality of phase detectors 76 and a power supply controller 78. The plurality of phase detectors 76 are provided between the plurality of matching devices 72 and the combiner 74, respectively. Each of the plurality of phase detector 76 is configured to detect a phase of the high frequency power transmitted via the corresponding matching device 72 from the corresponding high frequency power supply among the plurality of high frequency power supplies 70. The power supply controller 78 is configured to control the plurality of high frequency power supplies 70 to output the high frequency powers in preset phases. Further, the power supply controller 78 controls the plurality of high frequency power supplies 70 to set the high frequency powers to be outputted from the plurality of high frequency power supplies 70 to be of the preset phases, based on the phases detected by the plurality of phase detectors 76.

This high frequency power supply unit 60A generates a half-wave rectification wave as the aforementioned output wave. That is, through the combination of the plurality of high frequency powers, the high frequency power supply unit 60A generates the output wave (composite wave) in which the positive voltage component of the high frequency power of the fundamental frequency is reduced. In this way, the high frequency power supply unit 60A generates the output wave (composite wave) having a waveform similar to the half-wave rectification waveform. This high frequency power supply unit 60A is capable of generating the output wave (composite wave) while suppressing a loss of the high frequency powers from the high frequency power supplies 70.

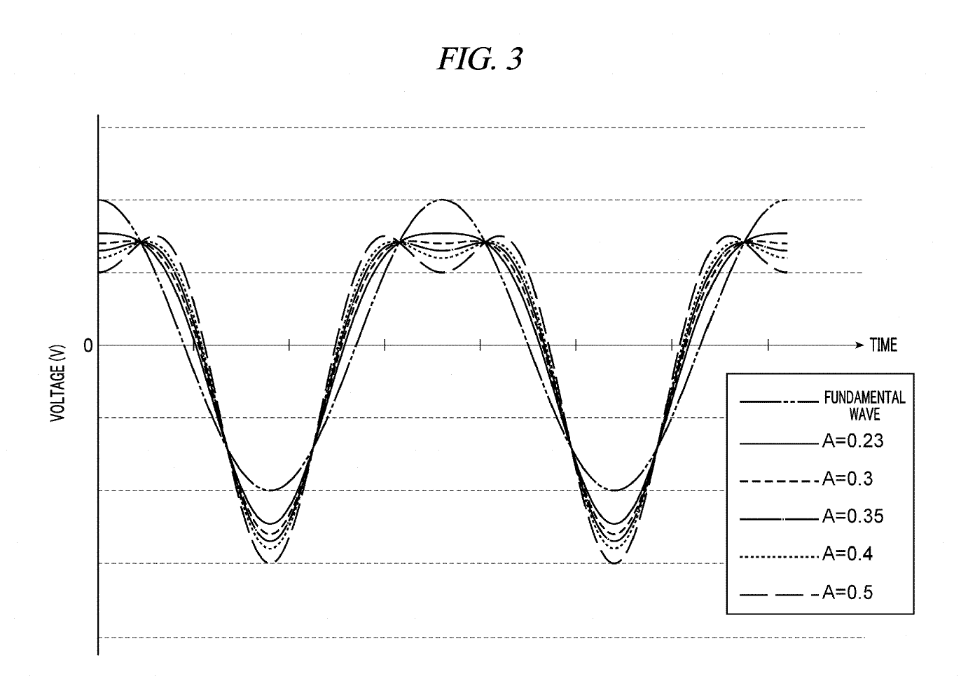

FIG. 3 is a diagram illustrating an example of the output wave which can be generated by the high frequency power supply unit shown in FIG. 2. FIG. 3 illustrates a voltage of an output wave (composite wave) generated by combination of a high frequency power RF1 having a fundamental frequency and a high frequency power RF2 having a frequency twice the fundamental frequency. Both the high frequency power RF1 and the high frequency power RF2 are sine waves, and a wave height value (peak to peak voltage) of the high frequency power RF2 is A times as large as a wave height value Vpp of the high frequency power RF1, and a phase difference between the high frequency power RF1 and the high frequency power RF2 is 270°. In FIG. 3, a horizontal axis represents a time, and a vertical axis indicates a voltage of the output wave. In FIG. 3, a voltage above 0 V is a positive voltage, and a voltage below 0 V is a negative voltage. Further, in FIG. 3, a fundamental wave refers to the high frequency power RF1, that is, the high frequency power of the fundamental frequency. As shown in FIG. 3, if “A” is equal to or larger than 0.23 and equal to or smaller than 0.4, it is possible to generate the output wave (composite wave) similar to the half-wave rectification waveform by using two high frequency power supplies, that is, a high frequency power supply configured to generate the high frequency power RF1 having the fundamental frequency and a high frequency power supply configured to generate the high frequency power RF2 having the frequency twice the fundamental frequency.

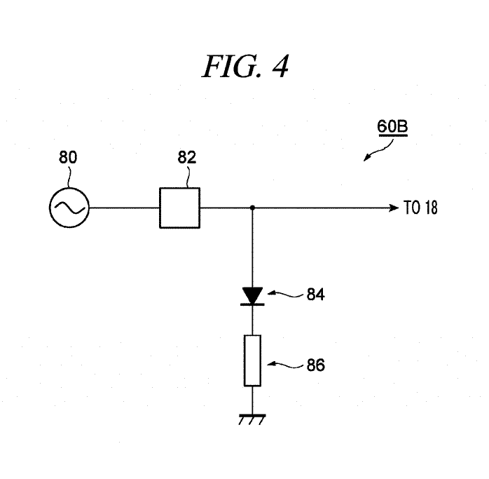

FIG. 4 is a diagram illustrating a high frequency power supply unit according to another exemplary embodiment. A high frequency power supply unit 60B depicted in FIG. 4 can be adopted as the high frequency power supply unit 60 of the plasma processing apparatus 10. The high frequency power supply unit 60B is equipped with a high frequency power supply 80, a matching device 82 and a half-wave rectifier 84. The high frequency power supply 80 is configured to generate a high frequency power of a fundamental frequency. The matching device 82 is connected to the high frequency power supply 80. The matching device 82 is equipped with a circuit configured to match an output impedance of the high frequency power supply 80 and an impedance at a load side. Further, the half-wave rectifier 84 is connected between the ground and a node between the matching device 82 and the lower electrode 18. The half-wave rectifier 84 is implemented by, by way of non-limiting example, a diode. An anode of the diode is connected to the node between the matching device 82 and the lower electrode 18, and a cathode of the diode is connected to the ground. Furthermore, a dummy load 86 may be provided between the cathode of the diode and the ground. The dummy load 86 may be an element configured to convert a high frequency power into heat.

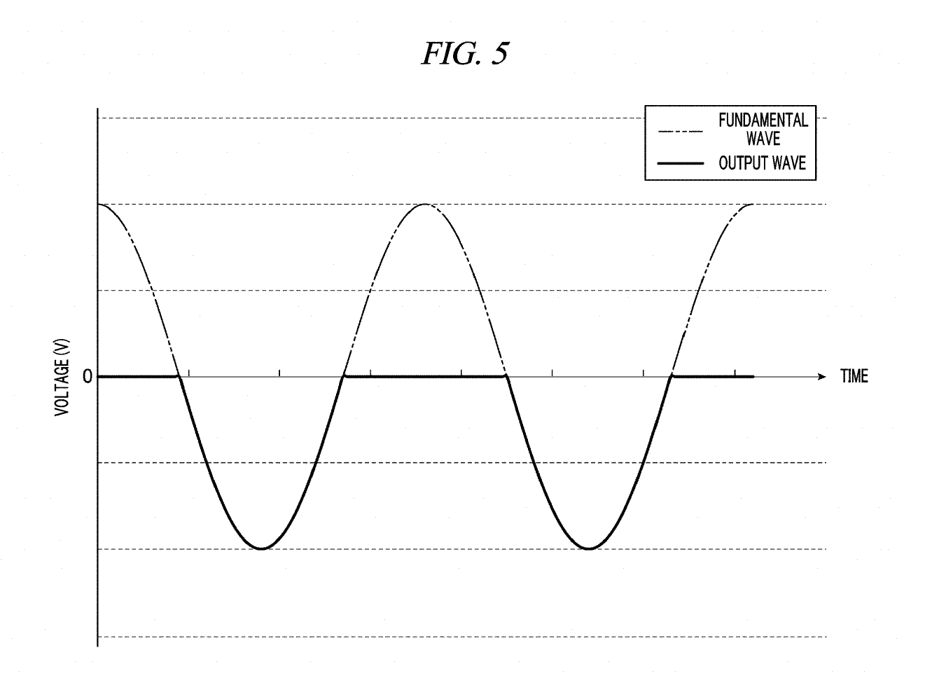

FIG. 5 is a diagram illustrating an example of an output wave generated by the high frequency power supply unit. In FIG. 5, a horizontal axis represents a time, and a vertical axis indicates a voltage of the output wave. In FIG. 5, a voltage above 0 V is a positive voltage, and a voltage below 0 V is a negative voltage. Further, in FIG. 5, a fundamental wave refers to the high frequency power outputted by the high frequency power supply 80. In the high frequency power supply unit 60B, when the voltage of the high frequency power generated by the high frequency power supply 80 is a positive voltage, the high frequency power is introduced to the ground by a rectifying operation of the half-wave rectifier 84. Meanwhile, when the voltage of the high frequency power generated by the high frequency power supply 80 is a negative voltage, the high frequency power is supplied to the lower electrode 18. Accordingly, according to the high frequency power supply unit 60B, it is possible to generate an output wave having a half-wave rectification waveform as shown in FIG. 5, that is, an output wave (half-wave) in which a positive voltage component is substantially completely removed.

According to the plasma processing apparatus 10 as stated above, since the output wave in which the positive voltage component is reduced is supplied to the lower electrode 18, an electric potential of the plasma generated within the chamber 12c is lowered. Accordingly, a potential difference between the plasma and the chamber main body 12 is reduced. As a result, energy of the ions irradiated to the chamber main body 12 is lowered. Accordingly, the particle generation from the chamber main body 12 is suppressed. Further, by setting the frequency (fundamental frequency) of the output wave from the high frequency power supply unit 60 to be low, it is possible to increase the energy of the ions irradiated to the processing target object while lowering the energy of the ions irradiated to the chamber main body.

Now, simulations conducted to evaluate the plasma processing apparatus according to the exemplary embodiment will be explained. In the following simulations, calculations are conducted upon the plasma processing apparatus in which the high frequency power supply unit 60 and the first high frequency power supply 62 are connected to the lower electrode 18, and the high frequency power supply unit 60B is used as the high frequency power supply unit 60.

First, Simulation No. 1 and Simulation No. 2 will be explained. In each of Simulation No. 1 and Simulation No. 2, an ion energy distribution (IED) of ions irradiated to the processing target object W and an ion energy distribution (IED) of ions irradiated to the chamber main body 12 are calculated. In Simulation No. 1, calculation is made under a setting that an output wave LF1 (half-wave) having a fundamental frequency of 400 kHz is supplied to the lower electrode from the high frequency power supply unit 60. Further, in Simulation No. 2, calculation is made under a setting that a high frequency power LF2 (sine wave) having a frequency of 400 kHz is supplied to the lower electrode. Further, the Vpp of the output wave LF1 (half-wave) in Simulation No. 1 and the Vpp of the high frequency power LF2 (sine wave) in Simulation No. 2 are set such that a maximum energy of the ions irradiated to the processing target object W is same in both simulations. Further, other settings of Simulation No. 1 and Simulation No. 2 are common as follows. Here, an A/C ratio is a value obtained by dividing an area of an anode facing the chamber by an area of a cathode facing the chamber.

<Common settings of Simulations No. 1 and No. 2>
Diameter of the chamber 12c: 30 mm
Distance between the upper electrode 30 and the placing table 16: 20 mm
Pressure of the chamber 12c: 30 mTorr (4 Pa)
A/C ratio: 7
Molecular weight of gas supplied into the chamber 12c: 40
Frequency of high frequency power from the first high frequency power supply 62: 100 MHz

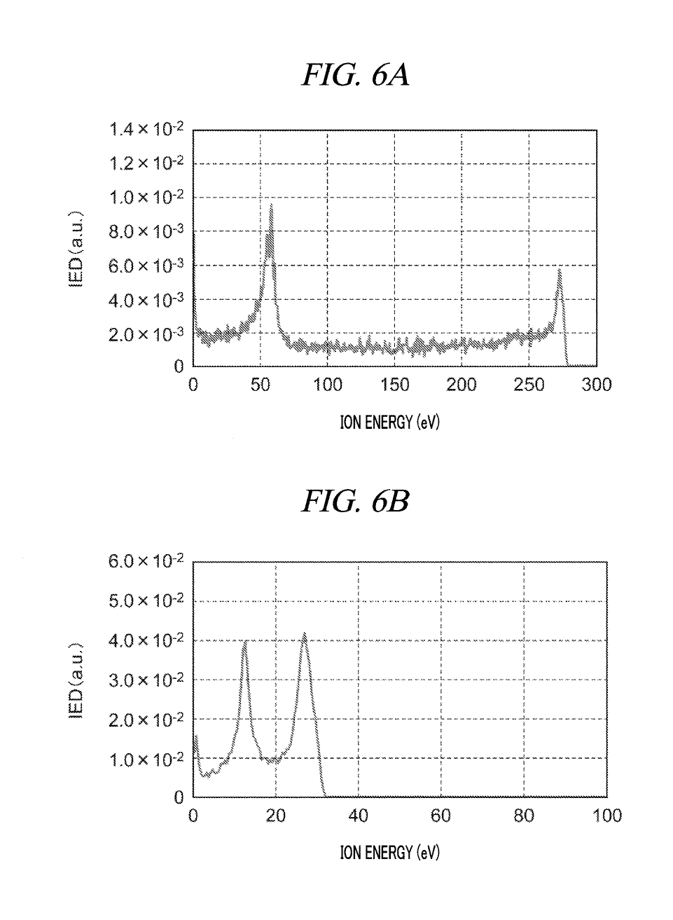

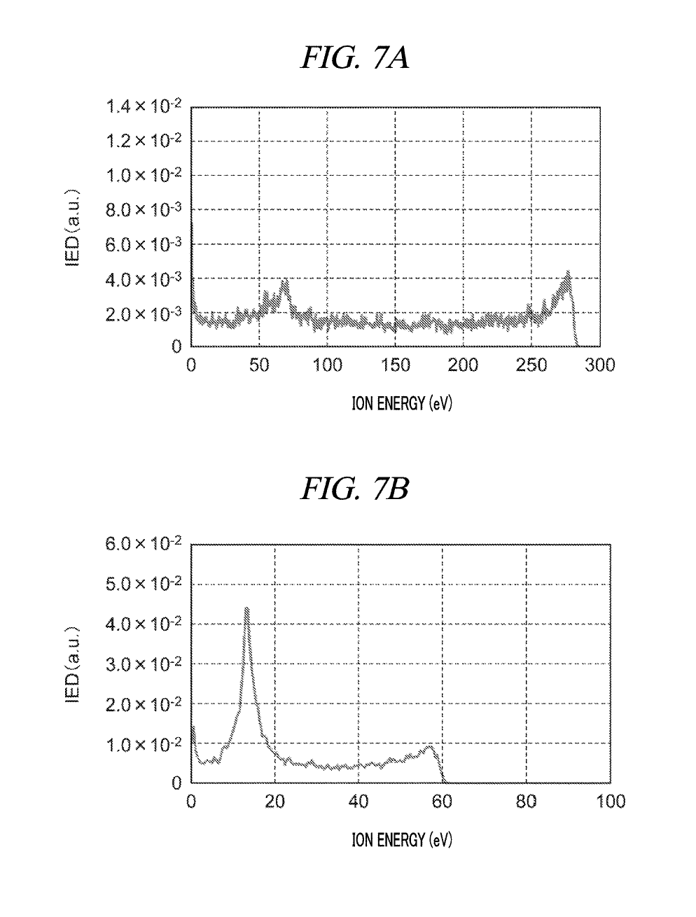

FIG. 6A shows the IED of the ions irradiated to the processing target object W calculated in Simulation No. 1, and FIG. 6B shows the IED of the ions irradiated to the chamber main body 12 calculated in Simulation No. 1. FIG. 7A shows the IED of the ions irradiated to the processing target object W calculated in Simulation No. 2, and FIG. 7B shows the IED of the ions irradiated to the chamber main body 12 calculated in Simulation No. 2.

As can be seen in FIG. 6A and FIG. 7A, the maximum energy of the ions irradiated to the processing target object W in Simulation No. 1 and the maximum energy of the ions irradiated to the processing target object W in Simulation No. 2 are substantially same. Accordingly, it is found out that by adjusting the Vpp of the output wave LF1 (half-wave) to be supplied to the lower electrode 18 from the high frequency power supply unit 60 as the high frequency power for bias (“high frequency bias power”), it is possible to irradiate, to the processing target object W, the ions having the same energy as that of the ions irradiated to the processing target object W in case of supplying the high frequency power LF2 (sine wave), which is a sine wave having the same frequency as the fundamental frequency of the output wave LF1 (half-wave), to the lower electrode 18. Further, in comparison of FIG. 6B and FIG. 7B, the maximum value of the energy of the ions irradiated to the chamber main body 12 in Simulation No. 1 is founded to be greatly reduced as compared to the maximum value of the energy of the ions irradiated to the chamber main body 12 in Simulation No. 2. Accordingly, it is found out that by supplying the output wave LF1 (half-wave) from the high frequency power supply unit 60 to the lower electrode 18 as the high frequency bias power, it is possible to reduce the energy of the ions irradiated to the chamber main body 12 greatly as compared to the case where the high frequency power LF2 as the sine wave having the same frequency as the fundamental frequency of the output wave LF1 (half-wave) is supplied to the lower electrode 18.

Now, Simulation No. 3 and Simulation No. 4 will be discussed. In Simulation No. 3, the frequency of the high frequency power for plasma generation from the first high frequency power supply 62 is changed to 50 MHz from the setting of Simulation No. 1, and, then, the IED of the ions irradiated to the processing target object W and the IED of the ions irradiated to the chamber main body 12 are calculated. Further, in Simulation No. 4, the frequency of the high frequency power for plasma generation from the first high frequency power supply 62 is changed to 50 MHz from the setting of Simulation No. 2, and, then, the IED of the ions irradiated to the processing target object W and the IED of the ions irradiated to the chamber main body 12 are calculated.

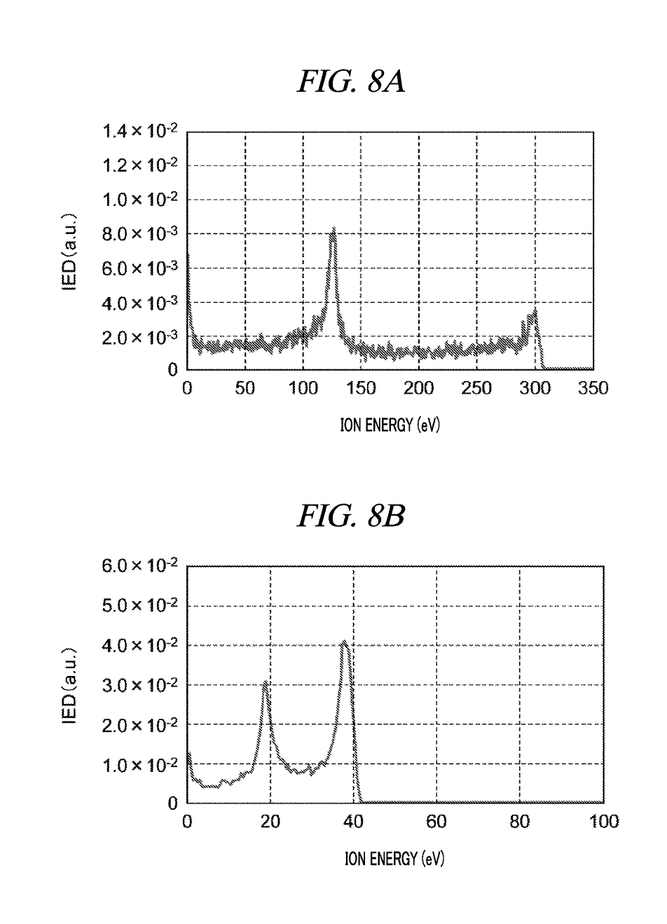

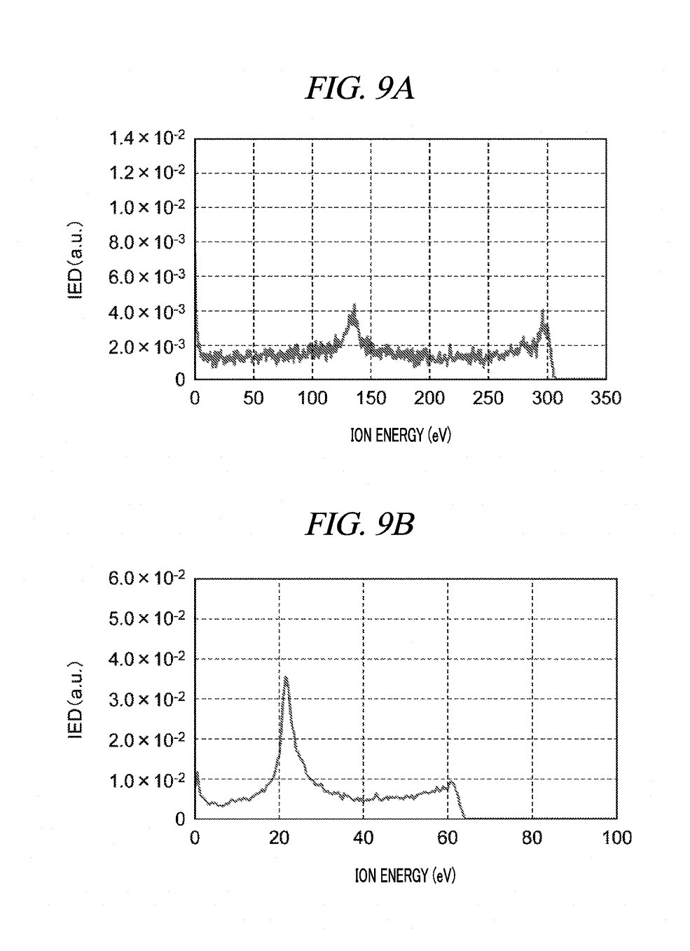

FIG. 8A shows the IED of the ions irradiated to the processing target object W calculated in Simulation No. 3, and FIG. 8B shows the IED of the ions irradiated to the chamber main body 12 calculated in Simulation No. 3. FIG. 9A shows the IED of the ions irradiated to the processing target object W calculated in Simulation No. 4, and FIG. 9B shows the IED of the ions irradiated to the chamber main body 12 calculated in Simulation No. 4.

As can be seen in FIG. 8A and FIG. 9A, the maximum value of the energy of the ions irradiated to the processing target object W in Simulation No. 3 and the maximum value of the energy of the ions irradiated to the processing target object W in Simulation No. 4 are substantially same. Further, in comparison of FIG. 8B and FIG. 9B, the maximum value of the energy of the ions irradiated to the chamber main body 12 in Simulation No. 3 is founded to be greatly reduced as compared to the maximum value of the energy of the ions irradiated to the chamber main body 12 in Simulation No. 4. Accordingly, it is found out from the results of Simulation Nos. 1 to 4 that the effect of the high frequency power supply unit 60, that is, the effect of suppressing the decrease of the energy of the ions irradiated to the processing target object W and reducing the energy of the ions irradiated to the chamber main body 12 does not substantially rely on the frequency of the high frequency power for plasma generation from the first high frequency power supply 62.

Now, Simulation No. 5 and Simulation No. 6 will be explained. In Simulation No. 5, an incident angle of ions reaching the processing target object W is calculated under the same settings as those of Simulation No. 1. Further, in Simulation No. 6, an incident angle of ions reaching the processing target object W is calculated under the same settings as those of Simulation No. 2.

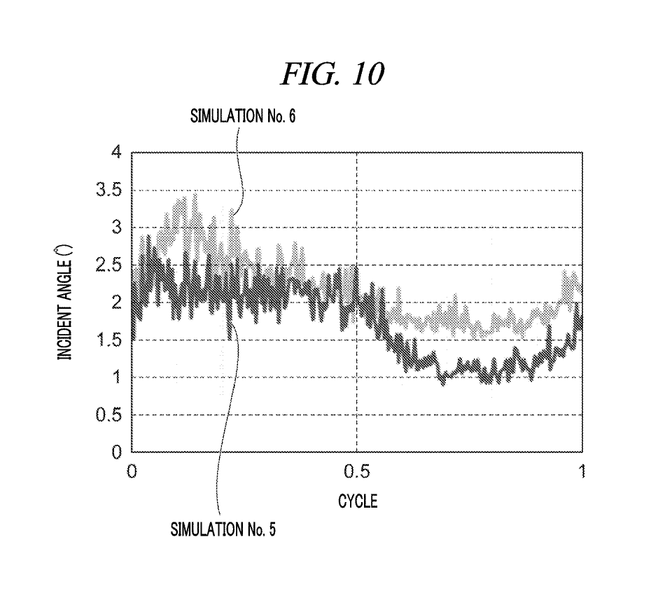

FIG. 10 shows the incident angles of the ions calculated in Simulation No. 5 and Simulation No. 6. In FIG. 10, a horizontal axis represents a cycle of the output wave LF1 (half-wave) and a cycle of the high frequency power LF2 (sine wave) of the high frequency power supply unit 60, and a vertical axis indicates an incident angle of the ions. Further, the incident angle of the ions vertically incident upon the processing target object W is 0°. As can be seen from FIG. 10, it is found out that by supplying the output wave LF1 (half-wave) from the high frequency power supply unit 60 to the lower electrode 18 as the high frequency bias power, it is possible to allow the ions to be incident upon the processing target object W more vertically as compared to the case where the high frequency power LF2, which is the sine wave having the same frequency as the fundamental frequency of the output wave LF1 (half-wave), is supplied to the lower electrode 18.

Now, Simulation No. 7 and Simulation No. 8 will be described. In Simulation No. 7, the molecular weight of the gas supplied into the chamber 12c is changed to 160 from the setting of Simulation No. 1, and, then, the IED of the ions irradiated to the processing target object W and the IED of the ions irradiated to the chamber main body 12 are calculated. In Simulation No. 8, the molecular weight of the gas supplied into the chamber 12c is changed to 160 from the setting of Simulation No. 2, and, then, the IED of the ions irradiated to the processing target object W and the IED of the ions irradiated to the chamber main body 12 are calculated.

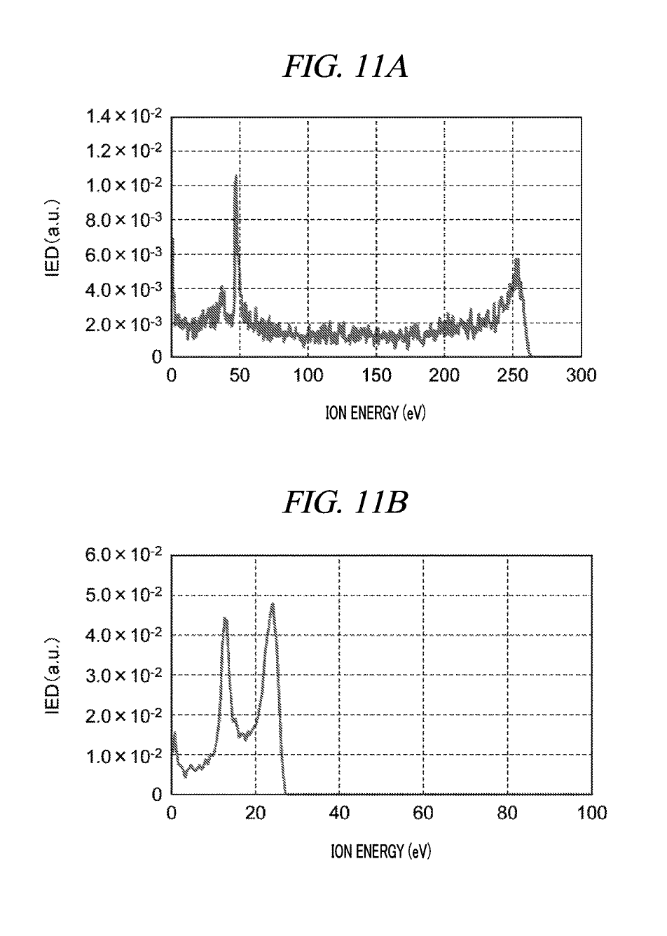

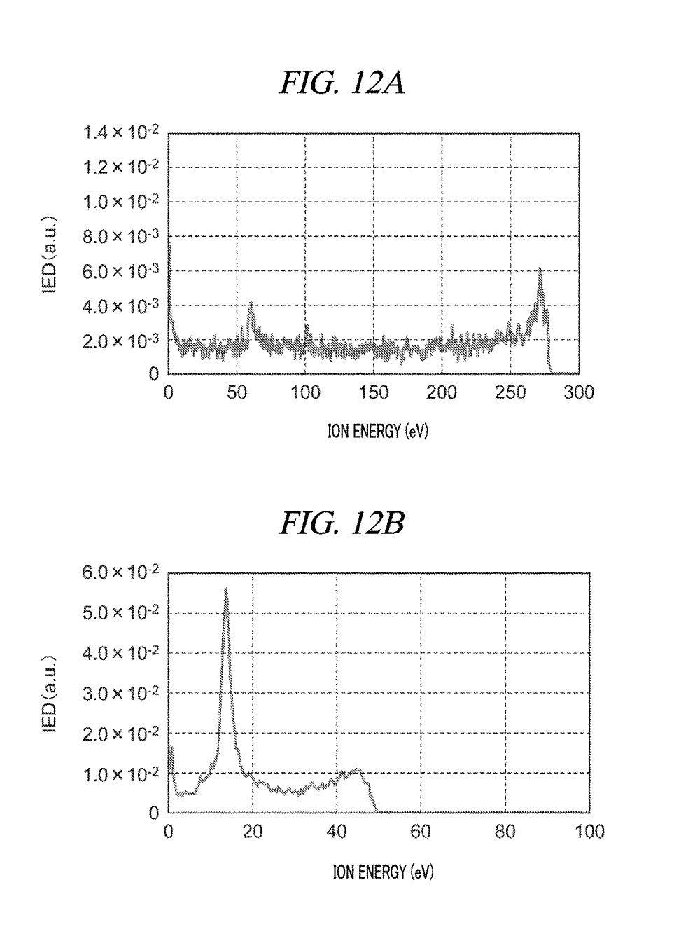

FIG. 11A shows the IED of the ions irradiated to the processing target object W calculated in Simulation No. 7, and FIG. 11B shows the IED of the ions irradiated to the chamber main body 12 calculated in Simulation No. 7. FIG. 12A shows the IED of the ions irradiated to the processing target object W calculated in Simulation No. 8, and FIG. 12B shows the IED of the ions irradiated to the chamber main body 12 calculated in Simulation No. 8.

As can be seen in FIG. 11A and FIG. 12A, the maximum value of the energy of the ions irradiated to the processing target object W in Simulation No. 7 and the maximum value of the energy of the ions irradiated to the processing target object W in Simulation No. 8 are substantially equal. Further, in comparison of FIG. 11B and FIG. 12B, the maximum value of the energy of the ions irradiated to the chamber main body 12 in Simulation No. 7 is founded to be greatly reduced as compared to the maximum value of the energy of the ions irradiated to the chamber main body 12 in Simulation No. 8. Accordingly, it is found out from the results of Simulation Nos. 1 and 2 and Simulation Nos. 7 and 8 that the effect of the high frequency power supply unit 60, that is, the effect of suppressing the decrease of the energy of the ions irradiated to the processing target object W while reducing the energy of the ions irradiated to the chamber main body 12 does not substantially rely on the molecular weight of the gas.

Now, Simulation Nos. 9 to 14 will be described. In Simulation Nos. 9 to 11, the A/C ratio is changed to 3.5, 7 and 10, respectively, from the setting of Simulation No. 1, and, then, the IED of the ions irradiated to the processing target object W and the IED of the ions irradiated to the chamber main body 12 are calculated in each simulation. In Simulation Nos. 12 to 14, the A/C ratio is changed to 3.5, 7 and 10, respectively, from the setting of Simulation No. 2, and, then, the IED of the ions irradiated to the processing target object W and the IED of the ions irradiated to the chamber main body 12 are calculated in each simulation. In each of Simulation Nos. 9 to 14, the maximum value E1 of the energy of the ions irradiated to the processing target object W divided by the maximum value E2 of the energy of the ions irradiated to the chamber main body 12, that is, E1/E2 is calculated. The higher the E1/E2 is, the higher the energy of the ions irradiated to the processing target object W is and the lower the energy of the ions irradiated to the chamber main body 12 is. Further, in general, since the electric potential of the plasma is increased as the A/C ratio gets smaller, the value of E1/E2 tends to be decreased.

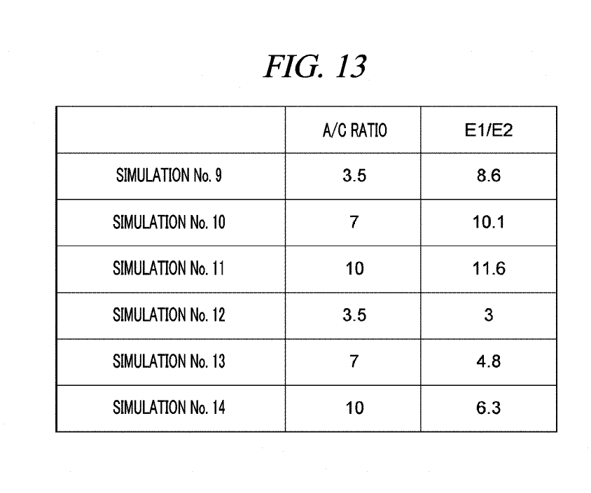

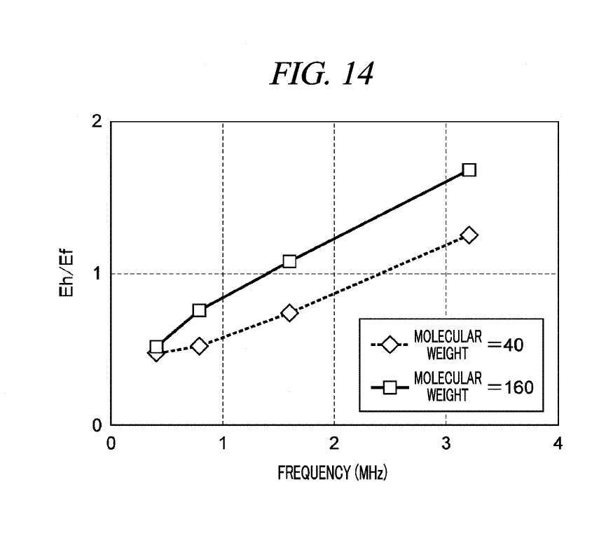

Results of Simulation Nos. 9 to 14 are shown in a table of FIG. 13. As shown in FIG. 13, the values of E1/E2 calculated in Simulation Nos. 9 to 11 are much larger than the values of E1/E2 obtained in Simulation Nos. 12 to 14. That is, in Simulation Nos. 9 to 11 in which the output wave LF1 (half-wave) from the high frequency power supply unit 60 is used as the high frequency bias power to be supplied to the lower electrode 18, the values of E1/E2 are larger than those in the cases (Simulation Nos. 12 to 14) in which the high frequency power LF2, which is the sine wave having the same frequency as the fundamental frequency of the output wave LF1 (half-wave), is supplied to the lower electrode 18. Thus, it is found out that the effect of the high frequency power supply unit 60, that is, the effect of suppressing the decrease of the energy of the ions irradiated to the processing target object W while reducing the energy of the ions irradiated to the chamber main body 12 is achieved even if the A/C ratio is considerably small. From this result, it is found out that the effect of the high frequency power supply unit 60 is exerted even in a plasma processing apparatus in which it is difficult to set the A/C ratio to be large, for example, in a plasma processing apparatus in which a high frequency power for plasma generation is supplied to the upper electrode 30.

Now, Simulation No. 15 to Simulation No. 30 will be explained. In Simulation No. 15 to Simulation No. 18, the fundamental frequency of the output wave LF1 (half-wave) of the high frequency power supply unit 60 is changed to 0.4 MHz, 0.8 MHz, 1.6 MHz and 3.2 MHz, respectively, from the setting of Simulation No. 1 and, then, the maximum value Eh of the energy of the ions irradiated to the chamber main body 12 is calculated. In Simulation No. 19 to Simulation No. 22, after changing the molecular weight of the gas to 160 from the setting of Simulation No. 1 and changing the fundamental frequency of the output wave LF1 (half-wave) of the high frequency power supply unit 60 to 0.4 MHz, 0.8 MHz, 1.6 MHz and 3.2 MHz, respectively, the maximum value Eh of the energy of the ions irradiated to the chamber main body 12 is calculated. In Simulation No. 23 to Simulation No. 26, after changing the frequency of the high frequency power LF2 (sine wave) to 0.4 MHz, 0,8 MHz, 1.6 MHz and 3.2 MHz from the setting of Simulation No. 2, the maximum value Ef of the energy of the ions irradiated to the chamber main body 12 is calculated. In Simulation No. 27 to Simulation No. 30, after changing the molecular weight of the gas to 160 from the setting of Simulation No. 2 and changing the frequency of the high frequency power LF2 (sine wave) to 0.4 MHz, 0.8 MHz, 1.6 MHz and 3.2 MHz, respectively, the maximum value Ef of the energy of the ions irradiated to the chamber main body 12 is calculated. Then, there are calculated values of the Eh of Simulation No. 15 divided by the Ef of Simulation No. 23, the Eh of Simulation No. 16 divided by the Ef of Simulation No. 24, the Eh of Simulation No. 17 divided by the Ef of Simulation No. 25, the Eh of Simulation No. 18 divided by the Ef of Simulation No. 26, the Eh of Simulation No. 19 divided by the Ef of Simulation No. 27, the Eh of Simulation No. 20 divided by the Ef of Simulation No. 28, the Eh of Simulation No. 21 divided by the Ef of Simulation No. 29 and the Eh of Simulation No. 22 divided by the Ef of Simulation No. 30.

FIG. 14 shows results thereof. A horizontal axis on a graph of FIG. 14 indicates the fundamental frequency of the output wave LF1 (half-wave) and the frequency of the high frequency power LF2 (sine wave), and a vertical axis indicates the value of Eh/Ef. Further, if the Eh/Ef is smaller than 1, the effect of the high frequency power supply unit 60 is achieved. That is, if the Eh/Ef is smaller than 1, the energy of the ions irradiated to the chamber main body 12 is reduced by supplying the output wave LF1 (half-wave) from the high frequency power supply unit 60 to the lower electrode 18 as the high frequency bias power, as compared to the case where the high frequency power LF2 as the sine wave having the same frequency as the fundamental frequency of the corresponding output wave is supplied to the lower electrode 18. Referring to FIG. 14, it is found out that the effect of the high frequency power supply unit 60 is achieved advantageously when the fundamental frequency of the output wave for bias is equal to or less than 1.4 MHz.

Now, Simulation No. 31 and Simulation No. 32 conducted to evaluate the plasma processing apparatus according to the exemplary embodiment will be explained. In Simulation No. 31 and Simulation No. 32, calculations are made upon the plasma processing apparatus having a configuration in which the high frequency power supply unit 60 and the first high frequency power supply 62 are connected to the lower electrode 18, and the high frequency power supply unit 60A is employed as the high frequency power supply unit 60. In Simulation No. 31 and Simulation No. 32, an output wave (composite wave) generated by combination of a high frequency power RF1 having a fundamental frequency (400 kHz) and a high frequency power RF2, which has a frequency (800 kHz) twice as high as the fundamental frequency and a wave height value A times as large as a wave height value of the high frequency power RF1, is used as the output wave from the high frequency power supply unit 60. The high frequency power RF1 and the high frequency power RF2 have a phase of 270°. In Simulation No. 31, the wave height value of the high frequency power RF2 is 0.23 times the wave height value of the high frequency power RF1, and in Simulation No. 32, the wave height value of the high frequency power RF2 is 0.4 times the wave height value of the high frequency power RF1. In Simulation No. 31 and Simulation No. 32, the IED of the ions irradiated to the processing target object W and the IED of the ions irradiated to the chamber main body 12 are calculated. Further, in Simulation No. 31 and Simulation No. 32, the other settings are common as follows.

<Common settings for Simulations No. 31 and No. 32>
Diameter of the chamber 12c: 30 mm
Distance between the upper electrode 30 and the placing table 16: 20 mm
Pressure of the chamber 12c: 30 mTorr (4 Pa)
A/C ratio: 7
Molecular weight of gas supplied into the chamber 12c: 40
Frequency of high frequency power from the first high frequency power supply 62: 100 MHz

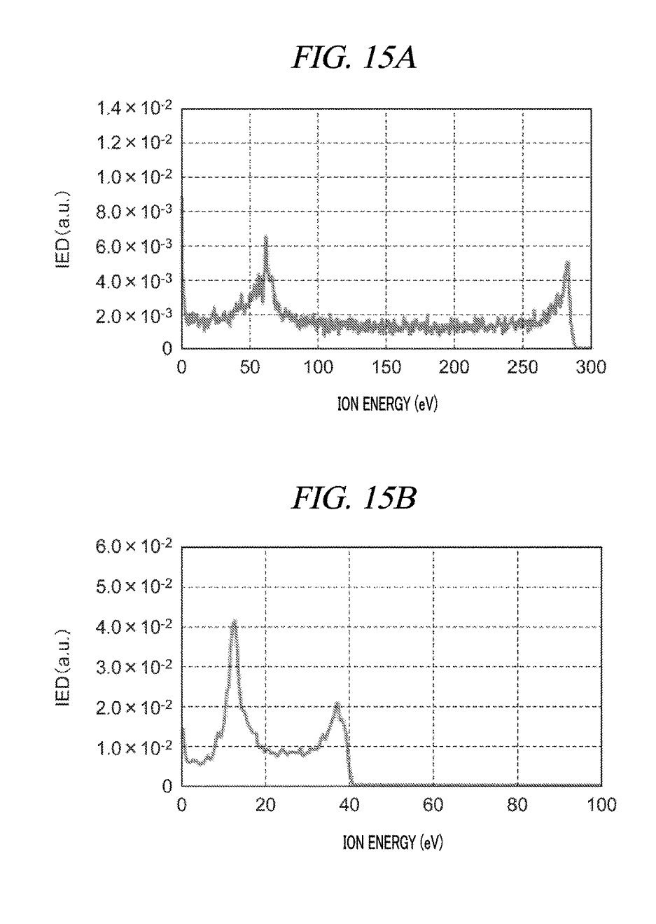

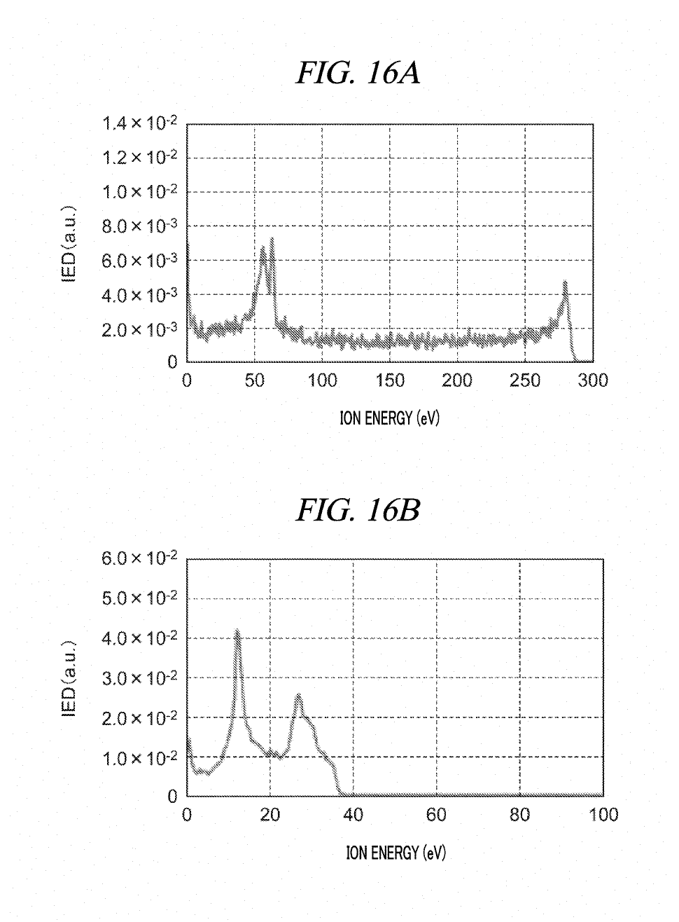

FIG. 15A shows the IED of the ions irradiated to the processing target object W calculated in Simulation No. 31, and FIG. 15B shows the IED of the ions irradiated to the chamber main body 12 calculated in Simulation No. 31. FIG. 16A shows the IED of the ions irradiated to the processing target object W calculated in Simulation No. 32, and FIG. 16B shows the IED of the ions irradiated to the chamber main body 12 calculated in Simulation No. 32.

As shown in FIG. 7A, FIG. 15A and FIG. 16A, the maximum value of the energy of the ions irradiated to the processing target object W in Simulation No. 31 and the maximum value of the energy of the ions irradiated to the processing target object W in Simulation No. 32 are approximately equal to the maximum value of the energy of the ions irradiated to the processing target object W in Simulation No. 2. Further, in comparison of FIG. 7B, FIG. 15B and FIG. 16B, the maximum value of the energy of the ions irradiated to the chamber main body 12 in Simulation No. 31 and the maximum value of the energy of the ions irradiated to the chamber main body 12 in Simulation No. 32 are found to be considerably smaller than the maximum value of the energy of the ions irradiated to the chamber main body 12 in Simulation No. 2. Thus, it is found out that even in case that the high frequency power supply unit 60A is used, the effect of the high frequency power supply unit 60, that is, the effect of suppressing the decrease of the energy of the ions irradiated to the processing target object W while reducing the energy of the ions irradiated to the chamber main body 12 is exerted.

Now, other high frequency power supply units which can be used as the high frequency power supply unit 60 will be explained. These other high frequency power supply units to be described below are configured to output a first output wave or a second output wave selectively. The first output wave is an output wave obtained by reducing a positive voltage component of a high frequency power having a fundamental frequency. The second output wave is an output wave obtained by reducing a negative voltage component of the high frequency power having the fundamental frequency.

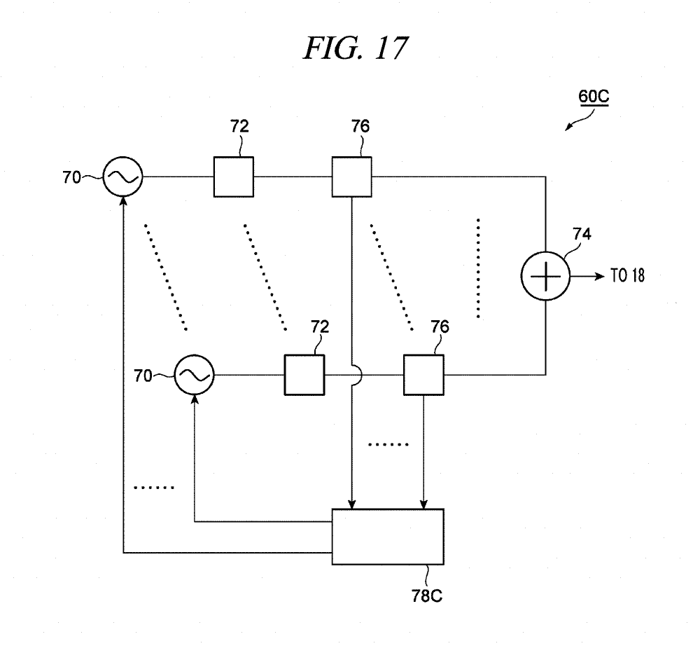

FIG. 17 is a high frequency power supply unit according to yet another exemplary embodiment. A high frequency power supply unit 60C shown in FIG. 17 may be employed as the high frequency power supply unit 60 of the plasma processing apparatus 10. The high frequency power supply unit 60C is different from the high frequency power supply unit 60A in that it has a power supply controller 78C instead of the power supply controller 78.

The high frequency power supply unit 60C is configured to output a first output wave or a second output wave selectively. The first output wave is an output wave which is the same as the aforementioned output wave generated by the high frequency power supply unit 60A, that is, an output wave (composite wave) which is generated by the combination of the plurality of high frequency powers outputted from the plurality of high frequency power supplies 70 and which is obtained by reducing a positive voltage component of the high frequency power having a fundamental frequency. The second output wave is an output wave (composite wave) which is generated by the combination of the plurality of high frequency powers outputted from the plurality of high frequency power supplies 70 and which is obtained by reducing a negative voltage component of the high frequency power having the fundamental frequency.

The power supply controller 78C is controlled by the control unit Cnt. If controlled by the control unit Cnt to generate the first output wave, the power supply controller 78C controls, in order to generate the first output wave, the plurality of high frequency power supplies 70 to output the high frequency powers in a phase previously set for the corresponding first output wave. Further, the power supply controller 78C controls the plurality of high frequency power supplies 70 to set the phases of the high frequency powers outputted from the plurality of high frequency power supplies 70 to the phase previously set for the first output wave, based on the phases detected by the plurality of phase detectors 76.

In addition, in case of generating the first output wave (composite wave) by combining the high frequency power RF1 having the fundamental frequency and a high frequency power RF2 having the frequency twice the fundamental frequency, the phase difference between the high frequency power RF1 and the high frequency power RF2 is set to 270°, and the wave height value of the high frequency power RF2 is set to be A times as large as the wave height value of the high frequency power RF1. Here, “A” is set to be equal to or larger than 0.23 and equal to or smaller than 0.4.

If controlled by the control unit Cnt to generate the second output wave, the power supply controller 78C controls, in order to generate the second output wave, the plurality of high frequency power supplies 70 to output the high frequency powers in a phase previously set for the corresponding second output wave. Further, the power supply controller 78C controls the plurality of high frequency power supplies 70 to set the phases of the high frequency powers outputted from the plurality of high frequency power supplies 70 to the phase previously set for the second output wave, based on the phases detected by the plurality of phase detectors 76.

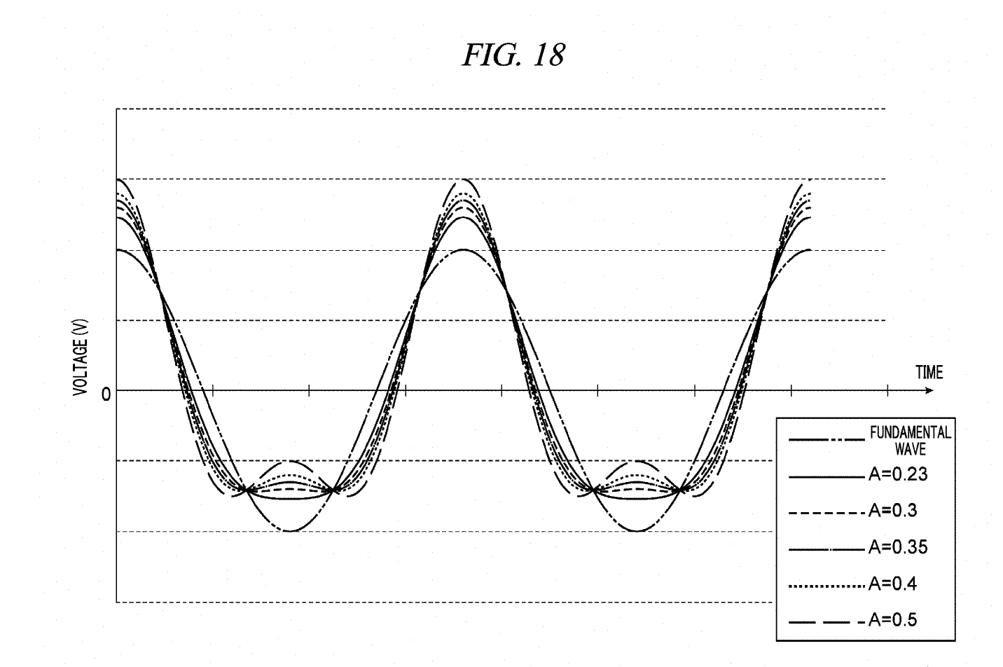

FIG. 18 is a diagram illustrating an example of the output wave which can be generated by the high frequency power supply unit depicted in FIG. 17. FIG. 18 shows a voltage of the second output wave (composite wave) generated by the combination of the high frequency power RF1 having the fundamental frequency and the high frequency power RF2 having the frequency twice the fundamental frequency. Both the high frequency power RF1 and the high frequency power RF2 are sine waves, and the wave height value (peak to peak voltage) of the high frequency power RF2 is A times as large as the wave height value Vpp of the high frequency power RF1. The phase difference between the high frequency power RF1 and the high frequency power RF2 is 90°. In FIG. 18, a horizontal axis represents a time, and a vertical axis indicates a voltage of the second output wave. In FIG. 18, a voltage above 0 V is a positive voltage, and a voltage below 0 V is a negative voltage. Further, in FIG. 18, a fundamental wave refers to the high frequency power RF1, that is, the high frequency power having the fundamental frequency. As shown in FIG. 18, if “A” is equal to or larger than 0.23 and equal to or smaller than 0.4, by using two high frequency power supplies, that is, a high frequency power supply configured to generate the high frequency power RF1 having the fundamental frequency and a high frequency power supply configured to generate the high frequency power RF2 having the frequency twice the fundamental frequency, the high frequency power supply unit 60C is capable of generating the second output wave (composite wave) similar to a half-wave rectification waveform in which the negative voltage component is removed.

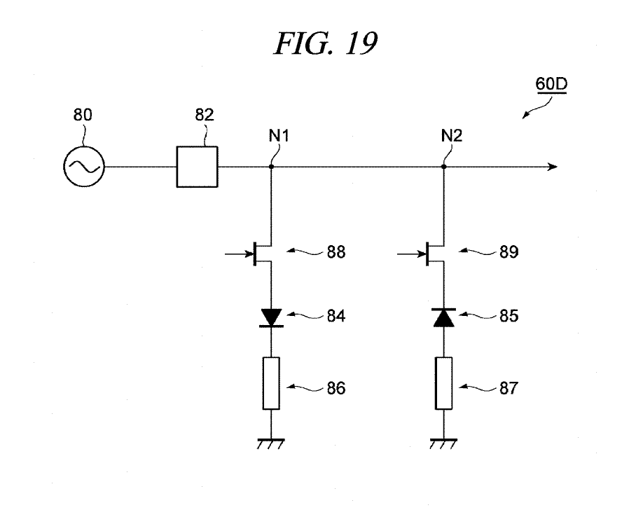

FIG. 19 is a diagram illustrating a high frequency power supply unit according to still yet another exemplary embodiment. A high frequency power supply unit 60D depicted in FIG. 19 may be adopted as the high frequency power supply unit 60 of the plasma processing apparatus 10. The high frequency power supply unit 60D is different from the high frequency power supply unit 60B in that it is further equipped with a half-wave rectifier 85, a switch 88 and a switch 89.

The high frequency power supply unit 60D is configured to output a first output wave or a second output wave selectively. The first output wave is an output wave which is the same as the above-described output wave generated by the high frequency power supply unit 60B, that is, an output wave (half-wave) in which a positive voltage component of a high frequency power outputted from the high frequency power supply 80 is substantially removed. The second output wave is an output wave (half-wave) in which a negative voltage component of the high frequency power outputted from the high frequency power supply 80 is approximately removed.

In the high frequency power supply unit 60D, the switch 88 is provided between the half-wave rectifier 84 and a node N1 between the matching device 82 and the lower electrode 18. The switch 88 is implemented by, by way of non-limiting example, a field effect transistor (FET). Further, in the high frequency power supply unit 60D, the half-wave rectifier 85 is connected between the ground and another node N2 between the rectifier 82 and the lower electrode 18. The half-wave rectifier 85 is implemented by, but not limited to, a diode. An anode of the diode is connected to the ground, and a cathode of the diode is connected to the node N2 via the switch 89. The switch 89 is implemented by, for example, a field effect transistor (FET). Further, a dummy load 87 may be provided between the anode of the diode of the half-wave rectifier 85 and the ground. The dummy load 87 may be configured to convert the high frequency power into heat.

The switch 88 and the switch 89 are controlled by the control unit Cnt. To elaborate, when outputting the first output wave from the high frequency power supply unit 60D, the switch 88 and the switch 89 are controlled to connect the node N1 and the half-wave rectifier 84 while disconnecting the node N2 from the half-wave rectifier 85. Further, when outputting the second output wave from the high frequency power supply unit 60D, the switch 88 and the switch 89 are controlled to connect the node N2 and the half-wave rectifier 85 while disconnecting the node N1 from the half-wave rectifier 84.

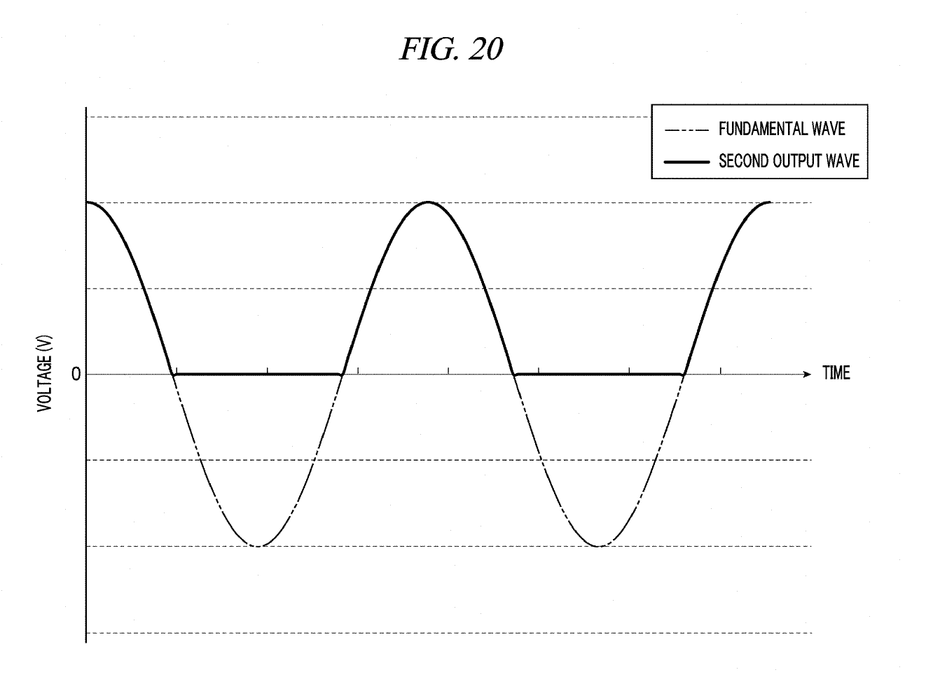

FIG. 20 illustrates an example of the second output wave generated by the high frequency power supply unit shown in FIG. 19. In FIG. 20, a horizontal axis represents a time, and a vertical axis indicates a voltage of the second output wave. In FIG. 20, a voltage above 0 V is a positive voltage, and a voltage below 0 V is a negative voltage. Further, in FIG. 20, a fundamental wave refers to the high frequency power outputted by the high frequency power supply 80. In the high frequency power supply unit 60D controlled to generate the second output wave, when the high frequency power generated by the high frequency power supply 80 is of the negative voltage, the high frequency power is introduced to the ground by the rectifying operation of the half-wave rectifier 85. Meanwhile, when the high frequency power generated by the high frequency power supply 80 is of the positive voltage, the high frequency power is supplied to the lower electrode 18. Accordingly, according to the high frequency power supply unit 60D, it is possible to generate the second output wave having a half-wave rectification waveform shown in FIG. 20, that is, an output wave (half-wave) in which the negative voltage component is removed substantially completely.

Now, Simulation No. 33 and Simulation No. 34 conducted to evaluate the plasma processing apparatus according to the present exemplary embodiment will be explained. In Simulation No. 33 and Simulation No. 34, calculations are made upon a plasma processing apparatus in which the high frequency power supply unit 60 and the first high frequency power supply 62 are connected to the lower electrode 18, and the high frequency power supply unit 60D is used as the high frequency power supply unit 60. In Simulation Nos. 33 and 34, calculations are made under a setting that the second output wave (half-wave) having the fundamental frequency of 400 kHz is supplied to the lower electrode from the high frequency power supply unit 60. Further, in Simulation No. 33, the Vpp (wave height value) of the second output wave is set such that ions having the substantially same energy as the maximum energy of the ions irradiated to the processing target object W in Simulation No. 2 are irradiated to the processing target object W. In Simulation No. 34, the Vpp of the second output wave is set to be lower than the Vpp of the second output wave in Simulation No. 33. In Simulation No. 33 and Simulation No. 34, the ion energy distribution (IED) of the ions irradiated to the processing target object W and the ion energy distribution (IED) of the ions irradiated to the chamber main body 12 are calculated. Further, in Simulation No. 33 and Simulation No. 34, the other settings are common as follows.

<Common settings of Simulation Nos. 33 and 34>
Diameter of the chamber 12c: 30 mm
Distance between the upper electrode 30 and the placing table 16: 20 mm
Pressure of the chamber 12c: 30 mTorr (4 Pa)
A/C ratio: 7
Molecular weight of a gas supplied into the chamber 12c: 40
Frequency of a high frequency power from the first high frequency power supply 62: 100 MHz

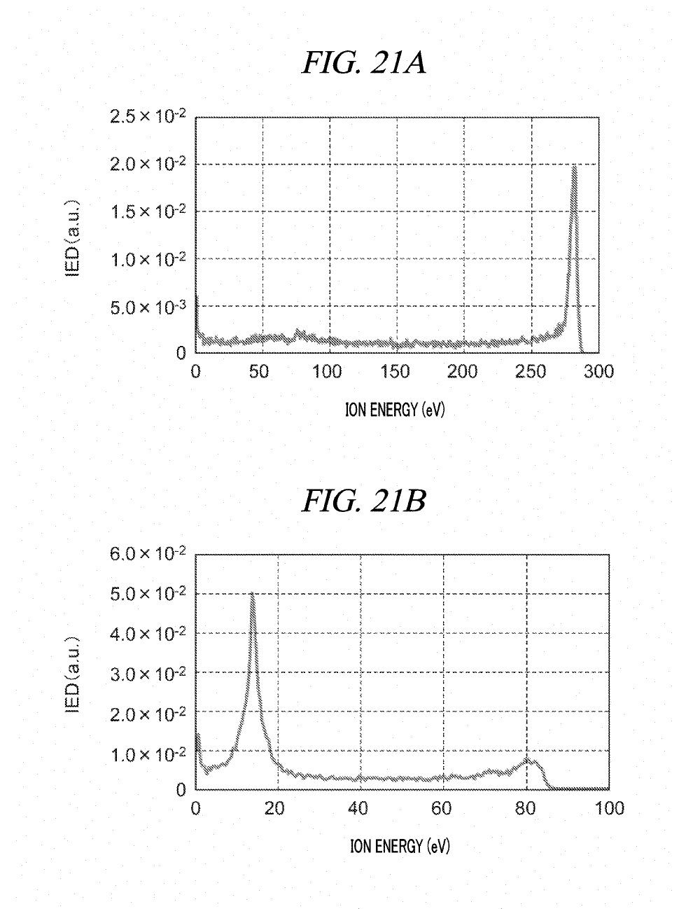

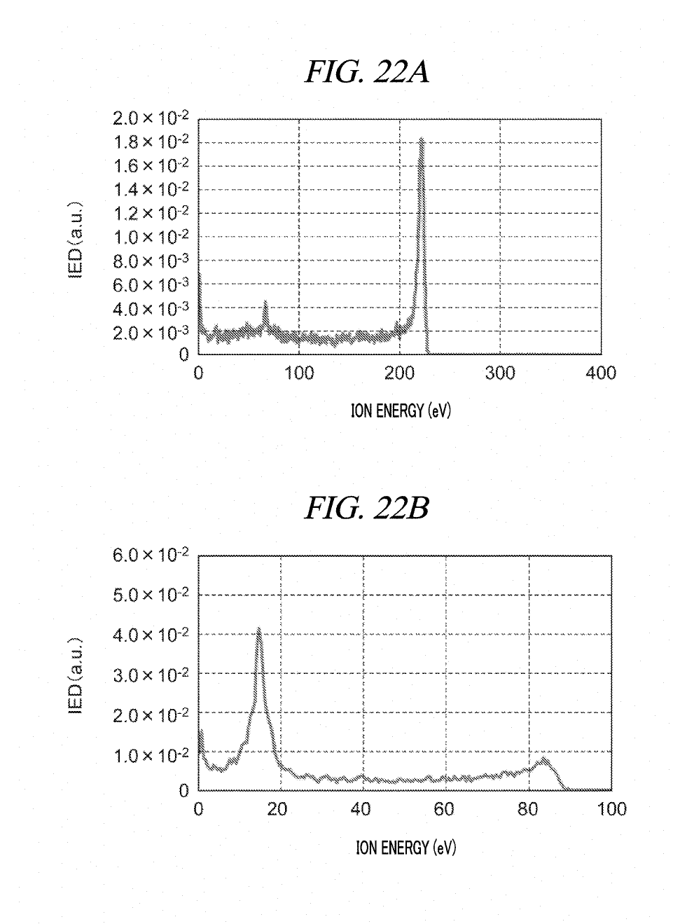

FIG. 21A shows the IED of the ions irradiated to the processing target object W calculated in Simulation No. 33, and FIG. 21B shows the IED of the ions irradiated to the chamber main body 12 calculated in Simulation No. 33. FIG. 22A shows the IED of the ions irradiated to the processing target object W calculated in Simulation No. 34, and FIG. 22B shows the IED of the ions irradiated to the chamber main body 12 calculated in Simulation No. 34.

Since the Vpp (wave height value) of the second output wave is set as stated above in Simulation No. 33, the maximum energy of the ions irradiated to the processing target object W in Simulation No. 33 is substantially equal to the maximum energy of the ions irradiated to the processing target object W in Simulation No. 2, as depicted in FIG. 7A and FIG. 21A. Meanwhile, in comparison of FIG. 7B and FIG. 21B, the energy of the ions irradiated to the chamber main body 12 in Simulation No. 33 is found to be considerably larger than the energy of the ions irradiated to the chamber main body 12 in Simulation No. 2. Accordingly, it is found out that by supplying the second output wave from the high frequency power supply unit 60 to the lower electrode 18 as the high frequency bias power, the energy of the ions irradiated to the chamber main body 12 can be increased as compared to the case where the high frequency power as the sine wave having the same frequency as the fundamental frequency of the second output wave is supplied to the lower electrode 18.

Moreover, as depicted in FIG. 7A and FIG. 22A, the maximum energy of the ions irradiated to the processing target object W in Simulation No. 34 is found to be considerably reduced as compared to the maximum energy of the ions irradiated to the processing target object W in Simulation No. 2. Meanwhile, in comparison of FIG. 7B and FIG. 22B, the energy of the ions irradiated to the chamber main body 12 in Simulation No. 34 is found to be considerably increased as compared to the energy of the ions irradiated to the chamber main body 12 in Simulation No. 2. Accordingly, it is found out that by supplying the second output wave from the high frequency power supply unit 60 to the lower electrode 18 as the high frequency bias power, the energy of the ions irradiated to the processing target object W is reduced, whereas the energy of the ions irradiated to the chamber main body 12 is increased.

As can be seen from the results of Simulation No. 33 and Simulation No. 34, by using the second output wave, it is possible to increase the energy of the ions irradiated to the chamber main body 12 while suppressing the energy of the ions irradiated to the placing table 16. Thus, the second output wave is applicable to, for example, waferless dry cleaning, that is, cleaning of the inner wall surface of the chamber main body 12 which is performed without placing a dummy wafer on the placing table 16.

So far, the various exemplary embodiments have been described. However, it should be noted that the exemplary embodiments are not meant to be anyway limiting and various changes and modifications may be made. By way of example, although the plasma processing apparatus 10 is configured as the capacitively coupled plasma processing apparatus, the high frequency power supply unit 60 may also be applicable to various other types of plasma processing apparatuses such as an inductively coupled plasma processing apparatus, a plasma processing apparatus using a surface wave such as a microwave, and so forth.

Further, although the high frequency power supply unit 60C and the high frequency power supply unit 60D are configured to selectively output the first output wave or the second output wave, they may be configured to output the second output wave only. In case that the high frequency power supply unit 60C (60D) is configured to output only the second output wave, the half-wave rectifier 84, the dummy load 86, the switch 88 and the switch 89 are removed from the high frequency power supply unit 60D, and the half-wave rectifier 85 is directly connected to the node N2.

### EXPLANATION OF REFERENCE NUMERALS

10: Plasma processing apparatus
12: Chamber main body
12c: Chamber
16: Placing table
18: Lower electrode
20: Electrostatic chuck
30: Upper electrode
50: Gas exhaust device
60: High frequency power supply unit
62: First high frequency power supply
64: Second high frequency power supply
60A: High frequency power supply unit
70: High frequency power supply
72: Matching device
74: Combiner
76: Phase detector
78: Power supply controller
60B: High frequency power supply unit
80: High frequency power supply
82: Rectifier
84: Half-wave rectifier

1. A plasma processing apparatus, comprising:
a chamber main body configured to provide a chamber therein and connected to a ground potential;
a placing table, having a lower electrode, provided within the chamber; and
a high frequency power supply unit electrically connected to the lower electrode and configured to generate an output wave for bias to be supplied to the lower electrode,
wherein the high frequency power supply unit is configured to generate the output wave in which a positive voltage component of a high frequency power having a fundamental frequency is reduced.

2. The plasma processing apparatus of claim 1,
wherein the high frequency power supply unit comprises:
multiple high frequency power supplies respectively configured to generate multiple high frequency powers having different frequencies n times or 2n times larger than the fundamental frequency (n denotes an integer equal to or higher than 1); and
a combiner configured to generate the output wave by combining the multiple high frequency powers.

3. The plasma processing apparatus of claim 1,
wherein the high frequency power supply unit comprises:
a high frequency power supply configured to generate the high frequency power having the fundamental frequency; and
a half-wave rectifier configured to remove the positive voltage component of the high frequency power generated from the high frequency power supply.

4. The plasma processing apparatus of claim 1,
wherein the plasma processing apparatus is configured as a capacitively coupled plasma processing apparatus, and
the plasma processing apparatus further comprises:
an upper electrode provided above the lower electrode; and
a first high frequency power supply connected to the upper electrode and configured to generate a high frequency power for plasma generation.

5. The plasma processing apparatus of claim 1,
wherein the fundamental frequency is equal to or less than 1.4 MHz.

6. The plasma processing apparatus of claim 1,
a second high frequency power supply connected to the lower electrode and configured to generate a high frequency power for bias having a frequency higher than the fundamental frequency.

7. The plasma processing apparatus of claim 1,
wherein the high frequency power supply unit is configured to selectively supply, to the lower electrode, a first output wave which serves as the output wave or a second output wave in which a negative voltage component of the high frequency power having the fundamental frequency is reduced.
